(19) United States
(12) Patent Application Publication
(10) Pub. No.: US 2023/0110701 A1
(43) Pub. Date: Apr. 13, 2023

(54) TECHNIQUES FOR DESIGN VERIFICATION OF DOMAIN CROSSINGS

(71) Applicant: TEXAS INSTRUMENTS INCORPORATED, Dallas, TX (US)

(72) Inventors: Sudhakar SURENDRAN, Bengaluru (IN); Venkatraman RAMAKRISHNAN, Bengaluru (IN)

(21) Appl. No.: 17/560,646

(22) Filed: Dec. 23, 2021

(30) Foreign Application Priority Data
Sep. 27, 2021 (IN) 202141043685

(51) Int. Cl. G06F 30/3323; G06F 30/327

(52) U.S. Cl. CPC G06F 30/3323; G06F 30/327

(57) ABSTRACT

A technique for domain crossing verification including receiving a first data object representation of an electrical circuit, performing a domain crossing check on the first data object representation to identify a domain crossing issue, receiving an indication of an assumption for the identified domain crossing issue, converting the first data object representation of the electrical circuit to a second data object representation of the electrical circuit, wherein the second data object representation is synthesized based on the first data object representation, determining one or more verification checks based on the second data object representation and the assumption for the identified domain crossing issue, and performing the one or more verification checks on the second data object representation of the electrical circuit.

### CROSS-REFERENCE TO RELATED APPLICATIONS

This application claims priority to India Provisional Application No. 202141043685, filed Sep. 27, 2021, which is hereby incorporated by reference.

### BACKGROUND

Modern integrated circuits (ICs), both analog and digital, are very complex with anywhere from tens of thousands of components to billions of components on a single IC. This complexity has led to automated design tools being used to design ICs over an IC design cycle. As a part of this IC design cycle, a register transfer level (RTL) description of the IC may be generated. This RTL is a high level, logical representation of an IC and the RTL describes what the IC design is doing, that is, how data is transformed as the data passes through the IC. The RTL description is often represented as RTL code, similar to a low-level software programming language. The RTL description can then be converted to a physical design by mapping the RTL code to geometric representations of electrical components, such as resisters, flip-flops, logic gates, etc. and how these electrical components are connected. This mapping may be performed using synthesis tools and this representation of electrical components and how the electrical components are connected may be in the form of a netlist. A netlist, or hardware description language (HDL), generally is a list of the electrical components of a circuit and a list of nodes each electronic component is connected with. In certain cases, attributes, structural information, physical parameters, or other information may also be included in the netlist.

### SUMMARY

An aspect of the present disclosure relates to a technique for domain crossing verification including receiving a first data object representation of an electrical circuit. The technique also includes performing a domain crossing check on the first data object representation to identify a domain crossing issue. The technique further includes receiving an indication of an assumption for the identified domain crossing issue. The technique also includes converting the first data object representation of the electrical circuit to a second data object representation of the electrical circuit, wherein the second data object representation is synthesized based on the first data object representation The technique further includes determining one or more verification checks based on the second data object representation and the assumption for the identified domain crossing issue and performing the one or more verification checks on the second data object representation of the electrical circuit.

Another aspect of the present disclosure relates to a non-transitory program storage device comprising instructions stored thereon to cause one or more processors to receive a first data object representation of an electrical circuit. The instructions further cause the one or more processors to perform a domain crossing check on the first data object representation to identify a domain crossing issue. The instructions also cause the one or more processors to receive an indication of an assumption for the identified domain crossing issue. The instructions further cause the one or more processors to convert the first data object representation of the electrical circuit to a second data object representation of the electrical circuit, wherein the second data object representation is synthesized based on the first data object representation. The instructions also cause the one or more processors to determine one or more verification checks based on the second data object representation and the assumption for the identified domain crossing issue and perform the one or more verification checks on the second data object representation of the electrical circuit.

Another aspect of the present disclosure relates to a device comprising one or more processors and a non-transitory program storage device comprising instructions stored thereon to cause the one or more processors to receive a first data object representation of an electrical circuit. The instructions further cause the one or more processors to perform a domain crossing check on the first data object representation to identify a domain crossing issue. The instructions also cause the one or more processors to receive an indication of an assumption for the identified domain crossing issue. The instructions further cause the one or more processors to convert the first data object representation of the electrical circuit to a second data object representation of the electrical circuit, wherein the second data object representation is synthesized based on the first data object representation. The instructions also cause the one or more processors to determine one or more verification checks based on the second data object representation and the assumption for the identified domain crossing issue and perform the one or more verification checks on the second data object representation of the electrical circuit.

### BRIEF DESCRIPTION OF THE DRAWINGS

For a detailed description of various examples, reference will now be made to the accompanying drawings in which:

FIGS. 1A and 1B illustrate examples of domain crossings, in accordance with aspects of the present disclosure.

FIG. 2 is a flow diagram illustrating a technique for design verification of domain crossings, in accordance with aspects of the present disclosure.

FIG. 3 is a is a block diagram of an embodiment of a computing device, in accordance with aspects of the present disclosure.

The same reference number is used in the drawings for the same or similar (either by function and/or structure) features.

### DETAILED DESCRIPTION

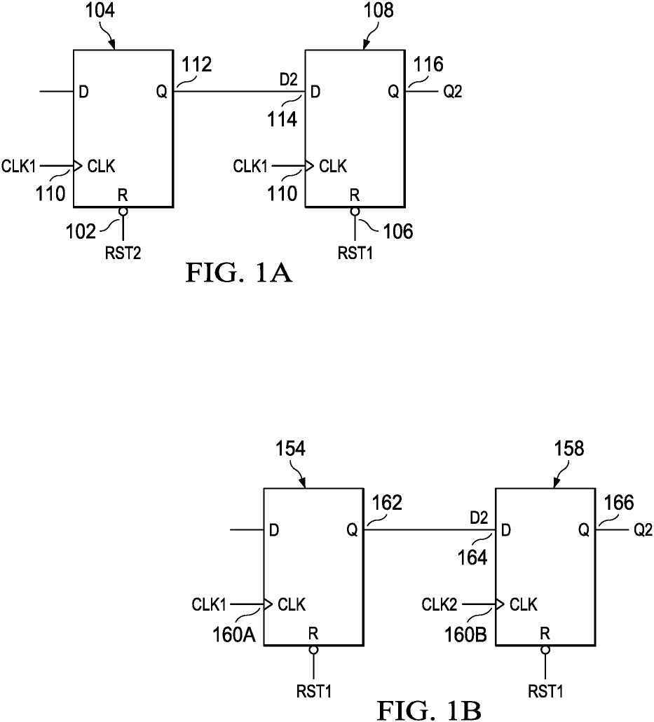

Often, a substantial amount of the design of an IC is performed at an RTL level to describe the logic and functionality of the IC. The RTL code may be a high-level logical representation of the logic of an IC being designed and the RTL code may comprise one or more a data object, such as a data file. The RTL level allows a design of the IC to be described at a relatively high level of abstraction using structures that are similar to those found in software programming languages, such as if statements, variables, mathematical operations, etc. As an example, the following RTL code example 1 illustrates a logical description of a source flip-flop 104 as shown in example circuit 100 of FIG. 1A. In RTL code example 1, the operation of the source flip-flop 104 is logically described as an if-else statement shown in lines 6-10.
1. module source_flop (D, CLK, R, Q) ;
2. input D, CLK, R;
3. output Q;
4. reg Q;
5. always @(posedge CLK or negedge R) begin
6. if (!R) begin
7. Q <= 0;
8. end else begin
9. Q <= D;
10. end
11. end
12. endmodule

### RTL Code Example 1

The RTL code may also describe connections such as connections between electronic components. As shown below, RTL code example 2 is an example of connection information describing the connections between source flip-flop 104 and a destination flip-flop 108.
1. module peripheral( /* port list */);
2. wire CLK1, RST1, RST2, D1, D2, Q2;
3. flop source_flop (.D (D1), .CLK(CLK1), .R(RST2), .Q(D2));
4. flop destination_flop (.D (D2), .CLK(CLKl), .R(RST1), .Q(Q2));
5. endmodule

### RTL Code Example 2

Synthesis tools can take the RTL and then synthesize a structural representation of the IC, for example as a netlist. With RTL, it is possible to describe a logic of an IC without specifying specific electronic components or details about the electronic components. However, the RTL could include issues that can give rise to subtle problems when synthesized into hardware. For example, the above example RTL code corresponds to portions of FIG. 1A and includes a reset 1 106 (RST1) and reset 2 102 (RST2). As shown, the reset 2 102 of the source flip-flop 104 is different from the reset 1 106 of destination flip-flop 108. As the source flip-flop 104 and the destination flip-flop 108 have the same clocks 110, the source flip-flop 104 and destination flip-flop 108 are synchronized, but the resets are asynchronous as the resets can occur at any time. It is possible that a reset may be set on the reset 2 102 of the source flip-flop 104, which can cause the output of the source flip-flop 104 to change on the output Q 112. Where the reset 1 106 of the destination flip-flop 108 is not be set, the changed value D2 on output Q 112 is set on input D 114 of destination flip-flop 108, causing the value Q2 of Q 116 to change. Depending on the time the value of Q 116 is read, the value on Q may be nondeterministic. This mismatch between the resets of a synchronous design may be referred to as a reset domain crossing (RDC).

Similarly, a clock domain crossing (CDC) may be present where a set of electrical components which are supposed to be synchronized, but have different clocks. For example, as shown in FIG. 1B, source flip-flop 154 is clocked using clock 1 160A and destination flip-flop 158 is clocked using clock 2 160B. If clock 1 160A and clock 2 160B are not, or become, phase aligned, a change on the output Q 162 may not be set at a time when input D 164 is to be read, resulting in the value Q2 of output Q 166 to change at an unexpected time.

Notably, the above described examples of RDC and CDC are intended to be illustrative and many other RDC and/or CDC paths are possible. In some cases, tools to check for various RDC and CDC paths are available. As an example, these domain crossing analysis tools may accept an RTL code and analyze the RTL code for possible RDC and/or CDC (e.g. domain crossing) issues. In some cases, the domain crossing analysis tools may generate a set of domain crossing issues. In some cases, the domain crossing analysis may be performed on portions of an overall IC. For example, an overall IC may include many circuit blocks which can significantly increase complexity. Generally, a circuit block may provide connectivity, services, and/or interfaces for a processor. Examples of circuit blocks include, but are not limited to, universal serial bus (USB), multimedia card (MMC), display connectivity, timers, analog to digital converters, graphics processing unit or other image processing hardware, sensors, PCI express (PCIe) interface, etc. In some cases, a processor and a number of circuit blocks may be integrated together on a single chip, for example, on a SoC.

Once the set of domain crossing issues are generated, circuit designers may review the set of domain crossing issues to check what may be causing the domain crossing issues to be raised by the domain crossing analysis tool. The domain crossing issues raised may be checked and resolved manually by circuit designers. For example, list of domain crossing issues may be generated and circuit designers may go down the list and address the domain crossing issues raised by making changes to the circuit, ensuring that any corner case caused by the domain crossing does not result in a system error, or otherwise addressing the issue. In some cases, a domain crossing issue raised may be addressed based on an assumption. These assumptions may be based on, for example, expected structural and/or operational configurations of the circuit under which the domain crossing issue raised does not apply. For example, where a domain crossing analysis has indicated a circuit may have a CDC crossing issue where a first component coupled to a first clock outputting to a second component coupled to a second clock, the circuit designer may know/believe that, in operation, the second component is clock gated or kept in reset when the output from the first component is presented and therefore, the CDC crossing issue is assumed to not apply as the second component is not going to be affected by the output of the first component.

Where the domain crossing analysis is performed on the RTL code, there may not be a mechanism to verify the assumptions. For example, verifying that the second component is clock gated or kept in reset may be performed, for example, by simulating portions of the IC. However, this simulation is performed using the netlist description of the structure of the IC that is synthesized from the RTL code. As the domain crossing analysis may be performed prior to the synthesis of the RTL code, there may not be a netlist to verify the assumptions on. Additionally, current domain crossing analysis tools are not linked to implementation verification tools, such as for netlist level verification or functional level analysis and timing verification, and there is no mechanism for defining specific verification techniques based on the assumptions.

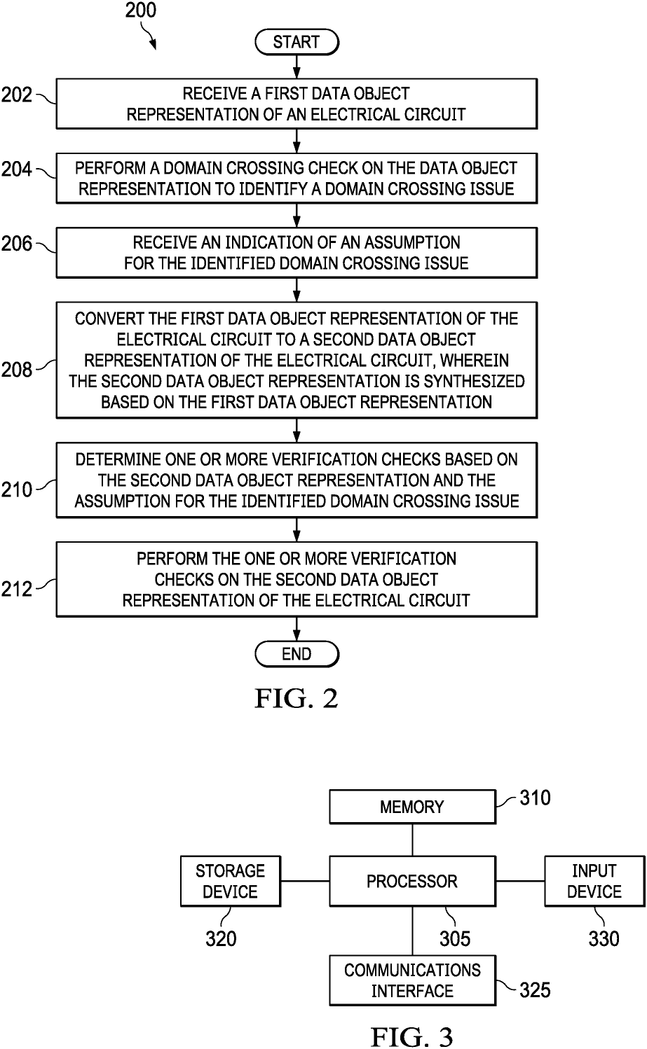

FIG. 2 is a flow diagram illustrating an overview of a technique for circuit verification, in accordance with aspects of the present disclosure. At block 202, a first data object representation of an electrical circuit is received. For example, a data object, such as a file may be received. The file may be a representation of an electrical circuit, such as an IC being designed. In some cases, the representation may be a logical representation of the electrical circuit, such as an RTL. In other cases, the representation may include hardware representations, such as with a netlist or HDL. In some cases, the representation may be for a portion of a larger electrical circuit. For example, the representation may be for a circuit block of an IC and/or SoC.

At block 204, a domain crossing check is performed on the data object representation to identify a domain crossing issue. For example, a set of clock domain crossing checks and/or reset domain crossing checks may be performed on the representation. The domain crossing checks may be performed on the representation of the electrical circuit. For example, the domain crossing checks may be performed based on the RTL file representing the electrical circuit. The different domain crossing checks may take various paths through the representation. For example, with a logical representation, such as an RTL, different paths through the representation may be performed using different data values. The domain crossing checks may identify one or more domain crossing issues. In some cases, the domain crossing issues returned may be associated with a particular path through the representation used by the domain crossing checking tool to identify the domain crossing issue. In some cases, the domain crossing issues along with path information, if available, may be output. This output may be output, for example, as a part of the representation of the electrical circuit, such as in the file. The output may also be output as a separate file, as metadata, or any other electronic representation. For example, a domain crossing checking tool may be run on an RTL file and the domain crossing checking tool may either generate a separate domain crossing issues file, or modify the RTL file to include the identified domain crossing issues. In some cases, the domain crossing issues may be presented, for example, to a user such as a chip designer via a user interface.

At block 206, an indication of an assumption for the identified domain crossing issue is received. For a particular domain crossing issue, the user may identify one or more assumptions made to dismiss the domain crossing issue and these assumptions may be recorded. For example, identified domain crossing issues may be presented to a user along with a list of possible assumptions. In some cases, the identified domain crossing issues may be presented by a user interface of the domain crossing checking tool. In some cases, assumptions may be tracked via a separate tool from the domain crossing checking tool. The domain crossing checking tool may also include a set of possible assumptions, where the different assumptions of the set of possible assumptions may be associated with domain crossing issues. In some cases, a list of assumptions may be determined based on a specific identified domain crossing issue. The determined list of assumptions associated with the identified domain crossing issue may be presented to the user, for example, along with the identified domain crossing issue. The user may then select one or more assumptions from the list of assumptions. Returning to a previous example for specifics, a circuit may have a CDC crossing issue where a first component coupled to a first clock outputting to a second component coupled to a second clock, the domain crossing checking tool may include an interface that presents a list of assumptions applicable to the CDC crossing issue, such as that the second component is clock gated, the second component is kept in reset, that the datapath to a destination of the second component is blocked when the output from the first component is presented, etc. The user may then select (e.g., provide) an assumption, such as that the second component is clock gated, from the list of assumptions. The provided assumptions may be stored as assumption information.

In some cases, the provided assumption may be associated, for example, with a path through the circuit block or other portions of the circuit, being analyzed. For example, the domain crossing checking tool may take various paths through the representation of the electrical circuit and these paths may involve different electrical components. This path, data input resulting in this path, and/or electrical components involved in the path may be recorded. For example, the representation of the portions (e.g., the RTL code) may be edited to include the logical path (or data input) resulting in this path, along with a representation of the received assumption. The path information (e.g., path, data input resulting in the path, and/or components involved in the path) for an assumption inherently associates the assumption with a portion of the representation of the electrical circuit. The path information may be included along with the assumption in the assumption information.

In some cases, the assumption information may be checked for internal consistency. Assumptions provided for different portions of the electrical circuit may occasionally be conflicting and checking for such conflicts can help reduce circuit development times. Returning to the example from above with a first component coupled to a first clock outputting to a second component coupled to a second clock having a CDC crossing issue. An assumption may be provided that the second component is clock gated when the first component outputs to the second component. Extending this example, the second component may be coupled to a third component in such a way as another CDC crossing issue is identified. The user may provide an assumption indicating that the second component is kept in reset. However, the second component may not be both clock gated and kept in reset. In some cases, path information may be used to perform internal consistency checking. In some cases, cross domain checking may be performed on a portion of the electrical circuit and multiple portions of the electrical circuit may be joined together. The internal consistency checking may be performed on such a joined representation.

The processes of blocks 202 through 206 may be performed for multiple iterations. Assumptions from a previous iteration may be fed back to later iterations, and paths that cross a domain and have an applied assumption from a previous iteration may be omitted from subsequent reports or may be reported along with an indication of the applied assumption. In this manner, the iterations may repeat until the design meets some threshold of quality.

At block 208, the first data object representation of the electrical circuit is converted to a second data object representation of the electrical circuit, wherein the second data object representation is synthesized based on the first data object representation. For example, a synthesis tool may convert an RTL description of an electrical circuit into a netlist description of the electrical circuit. As another example, the netlist description of the electrical circuit may be used by another synthesis tool, (e.g., routing and placement tools) to synthesize connections and a physical layout of the electrical circuit. In some cases, as a part of the conversion, the assumption information may be processed. The assumption information may be passed to the synthesis tool, for example, as a separate data object, such as a file, or along with the first data object representation, such as embedded in the file, as metadata to the file, etc. In some cases, this assumption information may be converted by the synthesis tool to a format compatible with the format of the synthesized second data object representation. In some cases, the assumption information may include path information indicating the portions of the first data object representation associated with a given assumption. As the synthesis tools may convert or otherwise transform the portions of the first data object representation into another representation of the electrical circuit, the synthesis tool may also identify a second portion of the second data object representation that correlates with the indicated portions of the first data object representation. For example, the synthesis tool may convert an indicated portion of the first data object representation (e.g., a logical data path) into a second portion of the second data object representation (e.g., a collection of physical device representations) and associate the assumption with this second portion.

At block 210 one or more verification checks may be determined based on the second data object representation and the assumption for the identified domain crossing issue. For example, assumptions may be associated with a set of verification checks. Table 1 below illustrates an example set of assumptions along with associated verification checks. Not all verification checks may apply to all possible design configurations or representations of the electrical circuit. Specific verification checks may be determined as appropriate for the particular assumption, the second data object representation, and/or the structure associated with the assumption (if available).

Table 1

| | |
|---|---|
| Assumption | Verification Check |
| Unsynchronized crossing or Fundamental crossing unit | Verify destination is clock gated, destination is kept in reset, or datapath to destination is blocked |
| Signals assumed to be constants | Verify that there is either no metastability (no crossing) when the signal transitions in the design to a known static configuration or perform the fundamental destination insensitivity checks |
| Conditions under which structural scenarios are waived | In-context analysis using these assumptions, verify that the structural scenarios are indeed inactive under the specified conditions, or perform the fundamental destination insensitivity checks under the necessary conditions |
| Unsynchronized resets | Perform fundamental destination insensitivity checks on the registers receiving such resets |
| Logic on asynchronous data and reset paths | Perform glitch checks on these lines - either glitches must be blocked or must not be generated for the relevant signal sequences |
| Clock / reset convergences | Perform glitch checks to ensure correctness of clock and reset signals |
| Convergence of multiple synchronized signals-general logic cone | Verify mutual exclusivity of signal toggles as conventionally done, fundamental destination insensitivity checks, path checks for verifying if only a single source is selected, check design functionality with relevant arbitration when there is a predefined priority, or verify active path for every signal when the logic cone is a regular reducing logic cone |
| Convergence of multiple synchronized signals controlling finite state machine states | Verify that there is only one metastability-prone signal that influences the state transitions from a given state and that this signal is independent of other converging signals or verify that there are safe return paths to known states when multiple metastability-prone signals control transitions from a given state |
| Other convergence of multiple synchronized signals | Verify design functionality with relevant coverage metrics for the converging graph |
| Fanout of unsynchronized data signal | Perform fundamental destination insensitivity checks on all the fanouts to ensure that at most one path is active or verify for convergence of such fanouts using standard convergence verification techniques |
| Reset domain crossings | Perform fundamental destination insensitivity checks or verify stability of source signals when the reset-crossing path is synchronized on the data path |
| Functional schemes used for clock domain crossings | Verify predictable data transfer through the scheme logic |
| Reset used in datapath | Verify stability of reset source |
| Asynchronous crossings on clock gates | Verify that the clocks are predictably OFF on the clock gate when the enable toggles, or perform fundamental destination checks on the registers clocked by the clock-gate |
| All scenarios inside IPs instantiated in an IC | Verify the assumptions for each structural scenario “in context” in the IC instantiation |

At block 212, one or more verification checks may be performed on the second data object representation of the electrical circuit. The determined verification checks may be executed to verify the correctness of the assumption. In some cases, the verification checks may be performed, for example, by a verification tool. The verification tool may, for example, use the second data object representation as input. Returning to the example above, where a circuit may have a CDC crossing issue where a first component coupled to a first clock outputting to a second component coupled to a second clock and there is a provided assumption that that the second component is clock gated when the first component output to the second component, this assumption may be verified, for example, by simulating the electrical circuit based on the netlist description and verifying that the second component is indeed clock gated. In some cases, the verification may be based on the path information. For example, the path or data input associated with the assumption may be used to inform the verification process by simulating the data input associated with the assumption being input to the electrical circuit. In cases where the determined verification checks do not succeed (e.g., the assumption is unverified) for a particular assumption, the particular assumption may be output, for example, for presentation to the user. In some cases, path information associated with the unverified assumption may also be presented.

In some cases, a verification check for an assumption may involve a formal method, such as a mathematical proof. In such cases, the verification checks may be performed, for example, by a user. For example, the verification tool may indicate to the user that a particular formal method is need to verify one or more assumptions.

As illustrated in FIG. 3, device 300 includes a processing element such as processor 305 that contains one or more hardware processors, where each hardware processor may have a single or multiple processor cores. Examples of processors include, but are not limited to, a central processing unit (CPU), image processor, or a microprocessor. Although not illustrated in FIG. 3, the processing elements that make up processor 305 may also include one or more other types of hardware processing components, such as graphics processing units (GPUs), application specific integrated circuits (ASICs), field-programmable gate arrays (FPGAs), and/or digital signal processors (DSPs). In certain cases, processor 305 may be configured to perform the tasks described in conjunction with steps 202-212 of FIG. 2.

FIG. 3 illustrates that memory 310 may be operatively and communicatively coupled to processor 305. Memory 310 may be a non-transitory computer readable storage medium configured to store various types of data. For example, memory 310 may include one or more volatile devices such as random access memory (RAM), registers, etc. Non-volatile storage devices 320 can include one or more disk drives, optical drives, solid-state drives (SSDs), tap drives, flash memory, electrically erasable programmable read-only memory (EEPROM), and/or any other type memory designed to maintain data for a duration time after a power loss or shut down operation. The non-volatile storage devices 320 may also be used to store programs that are loaded into the RAM when such programs executed.

Persons of ordinary skill in the art are aware that software programs may be developed, encoded, and compiled in a variety of computing languages for a variety of software platforms and/or operating systems and subsequently loaded and executed by processor 305. In one embodiment, the compiling process of the software program may transform program code written in a programming language to another computer language such that the processor 305 is able to execute the programming code. For example, the compiling process of the software program may generate an executable program that provides encoded instructions (e.g., machine code instructions) for processor 305 to accomplish specific, non-generic, particular computing functions.

After the compiling process, the encoded instructions may then be loaded as computer executable instructions or process steps to processor 305 from storage device 320, from memory 310, and/or embedded within processor 305 (e.g., via a cache or onboard ROM). Processor 305 may be configured to execute the stored instructions or process steps in order to perform instructions or process steps to transform the computing device into a non-generic, particular, specially programmed machine or apparatus. Stored data, e.g., data stored by a storage device 320, may be accessed by processor 305 during the execution of computer executable instructions or process steps to instruct one or more components within the computing device 300. Storage device 320 may be partitioned or split into multiple sections that may be accessed by different software programs. For example, storage device 320 may include a section designated for specific purposes, such as storing program instructions or data for updating software of the computing device 300. In one embodiment, the software to be updated includes the ROM, or firmware, of the computing device. In certain cases, the computing device 300 may include multiple operating systems. For example, the computing device 300 may include a general-purpose operating system which is utilized for normal operations. The computing device 300 may also include another operating system, such as a bootloader, for performing specific tasks, such as upgrading and recovering the general-purpose operating system and allowing access to the computing device 300 at a level generally not available through the general-purpose operating system. Both the general-purpose operating system and another operating system may have access to the section of storage device 320 designated for specific purposes.

The one or more communications interfaces 325 may include a radio communications interface for interfacing with one or more radio communications devices. In certain cases, elements coupled to the processor may be included on hardware shared with the processor. For example, the communications interfaces 325, storage device 320, and memory 310 may be included, along with other elements such as the digital radio, in a single chip or package, such as in a system on a chip (SOC). Computing device 300 may also include input and/or output devices, not shown, examples of which include sensors, cameras, human input devices, such as mouse, keyboard, touchscreen, monitors, display screen, tactile or motion generators, speakers, lights, etc. Processed input, for example from the image sensor, may be output from the computing device 300 via the communications interfaces 325 to one or more other devices.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. Circuits described herein are reconfigurable to include additional or different components to provide functionality at least partially similar to functionality available prior to the component replacement. Modifications are possible in the described examples, and other examples are possible within the scope of the claims.

What is claimed is:

1. A method, comprising:
receiving a first data object representation of an electrical circuit;
performing a domain crossing check on the first data object representation to identify a domain crossing issue;
receiving an indication of an assumption for the identified domain crossing issue;
converting the first data object representation of the electrical circuit to a second data object representation of the electrical circuit, wherein the second data object representation is synthesized based on the first data object representation;
determining one or more verification checks based on the second data object representation and the assumption for the identified domain crossing issue; and
performing the one or more verification checks on the second data object representation of the electrical circuit.

2. The method of claim 1, wherein the first data object representation comprises a logical representation of functionality of the electrical circuit.

3. The method of claim 1, wherein the second data object representation comprises a representation of electrical components of the electrical circuit.

4. The method of claim 1, wherein the domain crossing check comprises at least one of a clock domain crossing check or a reset domain crossing check.

5. The method of claim 1, further comprising outputting an indication of the one or more verification checks.

6. The method of claim 1, further comprising:
presenting a list of potential assumptions based on the identified domain crossing issue, wherein the received indication of the assumption is based on the list of potential assumptions.

7. The method of claim 1, further comprising:
associating the assumption with a first portion of the first data object representation associated with the domain crossing issue;
editing the first data object representation to include the assumption associated with the first portion; and
associating the assumption with a second portion of the second data object representation, the second portion of the second data object representation corresponding to the first portion of the first data object representation, wherein the one or more verification checks are performed based on the association of the assumption with the second portion.

8. A non-transitory program storage device comprising instructions stored thereon to cause one or more processors to:
receive a first data object representation of an electrical circuit;
perform a domain crossing check on the first data object representation to identify a domain crossing issue;
receive an indication of an assumption for the identified domain crossing issue;
convert the first data object representation of the electrical circuit to a second data object representation of the electrical circuit, wherein the second data object representation is synthesized based on the first data object representation;
determine one or more verification checks based on the second data object representation and the assumption for the identified domain crossing issue; and
perform the one or more verification checks on the second data object representation of the electrical circuit.

9. The non-transitory program storage device of claim 8, wherein the first data object representation comprises a logical representation of functionality of the electrical circuit.

10. The non-transitory program storage device of claim 8, wherein the second data object representation comprises a representation of electrical components of the electrical circuit.

11. The non-transitory program storage device of claim 8, wherein the domain crossing check comprises at least one of a clock domain crossing check or a reset domain crossing check.

12. The non-transitory program storage device of claim 8, further comprising outputting an indication of the one or more verification checks.

13. The non-transitory program storage device of claim 8, wherein the instructions further comprise instructions to cause the one or more processors to:
present a list of potential assumptions based on the identified domain crossing issue, wherein the received indication of the assumption is based on the list of potential assumptions.

14. The non-transitory program storage device of claim 8, wherein the instructions further comprise instructions to cause the one or more processors to:
associate the assumption with a first portion of the first data object representation associated with the domain crossing issue;
edit the first data object representation to include the assumption associated with the first portion; and
associate the assumption with a second portion of the second data object representation, the second portion of the second data object representation corresponding to the first portion of the first data object representation, wherein the one or more verification checks are performed based on the association of the assumption with the second portion.

15. A device comprising:
one or more processors; and
a non-transitory program storage device comprising instructions stored thereon to cause the one or more processors to:
receive a first data object representation of an electrical circuit;
perform a domain crossing check on the first data object representation to identify a domain crossing issue;
receive an indication of an assumption for the identified domain crossing issue;
convert the first data object representation of the electrical circuit to a second data object representation of the electrical circuit, wherein the second data object representation is synthesized based on the first data object representation;
determine one or more verification checks based on the second data object representation and the assumption for the identified domain crossing issue; and
perform the one or more verification checks on the second data object representation of the electrical circuit.

16. The device of claim 15, wherein the first data object representation comprises a logical representation of functionality of the electrical circuit.

17. The device of claim 15, wherein the second data object representation comprises a representation of electrical components of the electrical circuit.

18. The device of claim 15, wherein the domain crossing check comprises at least one of a clock domain crossing check or a reset domain crossing check.

19. The device of claim 15, further comprising outputting an indication of the one or more verification checks.

20. The device of claim 15, wherein the instructions further comprise instructions to cause the one or more processors to present a list of potential assumptions based on the identified domain crossing issue, wherein the received indication of the assumption is based on the list of potential assumptions.
